(19) United States
(12) Patent Application Publication
(10) Pub. No.: US 2026/0096031 A1
(43) Pub. Date: Apr. 2, 2026

(54) BRACKET FOR ELECTRONIC DEVICE PLACED ON VERTICAL SURFACE

(71) Applicant: SMARTPOINT LIMITED LIABILITY COMPANY, MOSCOW (RU)

(72) Inventors: Tatiana Nikolaevna MOSALOVA, Moscow (RU); Artem Aleksandrovich KRAVCHENKO, Moscow (RU)

(21) Appl. No.: 19/206,885

(22) Filed: May 13, 2025

(30) Foreign Application Priority Data
Sep. 30, 2024 (RU) 2024129097

(51) Int. Cl. H05K 5/02; F21V 21/02; F21V 23/04; H04R 1/02; H04R 3/00

(52) U.S. Cl. CPC H05K 5/0204; F21V 21/02; H04R 1/026; F21V 23/04; H04R 3/00

(57) ABSTRACT

The proposed invention relates to the field of computer engineering and can be used to control electronic devices. The technical result achieved by implementing the claimed invention, in addition to the invention realizing its purpose, is the elimination of the disadvantages of analogues and thus ensuring the rapid disconnection of the bracket and the device placed on it, while ensuring the usual reliability of placing the device on a vertical surface. Another technical result achieved by implementing the claimed invention, in addition to the invention realizing its purpose, is also ensuring precise positioning of the device in space and ensuring a rapid change of its operating mode and/or settings.

### FIELD OF INVENTION

The present invention relates to the field of computer technology and can be used to control electronic devices.

### DESCRIPTION OF THE RELATED ART

There are various known methods for determining a device's position in space, such as those described in patent documents US20150331084A1 (D1), U.S. Pat. No. 9,681,267B2 (D2), U.S. Pat. No. 11,051,105B2 (D3).

A common disadvantage of conventional means for determining a device's position in space is that they have low accuracy and that they are also unable to determine the function of the premises, where the device is located, which makes it impossible to use the known methods to control the device depending on its environment.

Therefore, there is a need in the field for a simple and quick method for controlling an electronic device depending on its environment.

The solution of D3 can be considered the closest prior art to the claimed invention.

### SUMMARY OF THE INVENTION

The technical problem to be solved by the claimed invention is to create brackets, and/or systems, and/or sets, and/or products, and/or devices that do not possess the drawbacks of the prior art and enable the bracket to be quickly disconnected from the device that is placed on it. Another technical problem to be solved by the claimed invention is to create brackets, and/or systems, and/or sets, and/or products, and/or devices that do not possess the drawbacks of the prior art and enable the bracket to be quickly disconnected from the device in order to quickly change its operation mode and/or settings, which can be useful, for example, but not limited to, in order to accurately position the device within its environment and to change its operation mode and/or settings depending on its environment. Another technical problem to be solved by the claimed invention is to expand the technical means, namely brackets for electronic devices that are placed on a vertical surface and/or electronic devices that are capable of changing their operation mode and/or settings depending on their environment.

The objective of the proposed invention, in addition to it performing its functions, is to eliminate the drawbacks of the prior art and thus to enable the bracket to be quickly disconnected from the device that is placed on it while maintaining the usual security of device placement on a vertical surface. Another objective of the proposed invention, in addition to it performing its functions, is also to enable accurate positioning of the device in space and quick change of its operation mode and/or settings.

The objective of the present invention is achieved by a bracket for an electronic device placed on a vertical surface, the bracket being an element that is fixed to a vertical surface to form a ledge, adapted to place the ledge into a recess provided in a side of the electronic device that faces the vertical surface; wherein the ledge comprises at least one ferromagnetic or magnetic element, and the recess holds a corresponding opposite magnetic or ferromagnetic element, so that said opposite element contacts the corresponding ferromagnetic or magnetic element of the bracket to create a magnetic coupling when the ledge is placed into the recess; wherein the recess is designed, so as to provide a shift of the corresponding opposite ferromagnetic or magnetic element relative to the corresponding magnetic or ferromagnetic element of the bracket; wherein the bracket is equipped with a passive identification means, and the electronic device is equipped with a reader adapted to interact with said identification means; and wherein the electronic device comprises at least a processor; and a memory that stores at least a program code, which, when executed by the processor, enables the reader to interact with the passive identification means to receive an identification signal.

### BRIEF DESCRIPTION OF THE DRAWINGS

Exemplary embodiments of the present invention are described in further detail below with references made to the attached drawings, included herein by reference:

FIG. 1 illustrates an exemplary, non-limiting, embodiment of the proposed bracket 100.

FIG. 2 illustrates an exemplary, non-limiting, embodiment of device 200 that is connected to bracket 100.

FIG. 3 illustrates a different exemplary, non-limiting, embodiment of device 200 that is connected to bracket 100.

FIG. 4 illustrates exemplary, non-limiting, options of connecting bracket 100 and device 200.

FIG. 5 illustrates an exemplary, non-limiting, way of placing bracket 100 in recess 202 of device 200.

FIG. 6 illustrates a different exemplary, non-limiting, embodiment of the proposed bracket 100.

FIG. 7 illustrates an exemplary, non-limiting, embodiment of device 200 that is connected to bracket 100 according to the second embodiment.

FIG. 8 illustrates an exemplary, non-limiting, embodiment of shifting ferromagnetic element 201 (not shown in this drawing) relative to magnetic element 101 in one embodiment of device 200 when using bracket 100 according to the second embodiment.

FIG. 9 illustrates an exemplary, non-limiting, embodiment of shifting ferromagnetic element 201 (not shown in this drawing) relative to magnetic element 101 in another embodiment of device 200 when using bracket 100 according to the second embodiment.

FIG. 10 illustrates an exemplary, non-limiting, rear view of two exemplary embodiments of device 200 designed for use with bracket 100 according to the first embodiment.

FIG. 11 illustrates an exemplary, non-limiting, rear view of two exemplary embodiments of device 200 designed for use with bracket 100 according to the second embodiment.

FIG. 12 illustrates an exemplary, non-limiting, overall scheme for the proposed system 500.

### DETAILED DESCRIPTION OF THE PREFERRED EMBODIMENTS

According to a preferred embodiment of the present invention, there is provided a bracket for an electronic device placed on a vertical surface, the bracket being an element that is fixed to a vertical surface to form a ledge, adapted to place the ledge into a recess provided in a side of the electronic device that faces the vertical surface; wherein the ledge comprises at least one ferromagnetic or magnetic element, and the recess holds a corresponding opposite magnetic or ferromagnetic element, so that said opposite element contacts the corresponding ferromagnetic or magnetic element of the bracket to create a magnetic coupling when the ledge is placed into the recess; wherein the recess is designed, so as to provide a shift of the corresponding opposite ferromagnetic or magnetic element relative to the corresponding magnetic or ferromagnetic element of the bracket; wherein the bracket is equipped with a passive identification means, and the electronic device is equipped with a reader adapted to interact with said identification means; and wherein the electronic device comprises at least a processor; and a memory that stores at least a program code, which, when executed by the processor, enables the reader to interact with the passive identification means to receive an identification signal.

According to an exemplary embodiment of the present invention, there is provided a bracket according to the present disclosure, characterized in that the electronic device is an acoustic device that additionally comprises at least a sound output means controlled by the processor.

According to an exemplary embodiment of the present invention, there is provided a bracket according to the present disclosure, characterized in that the electronic device is a lighting device that additionally comprises at least a light source controlled by the processor.

According to an exemplary embodiment of the present invention, there is provided a bracket according to the present disclosure, characterized in that the electronic device is an IoT device that additionally comprises at least a receiver and a transmitter adapted to transmit a control signal, both the receiver and the transmitter being controlled by the processor.

According to an exemplary embodiment of the present invention, there is provided a bracket according to the present disclosure, characterized in that the electronic device is an image output device that additionally comprises at least a display controlled by the processor.

According to an exemplary embodiment of the present invention, there is provided a bracket according to the present disclosure, characterized in that the memory additionally stores at least a program code, which, when executed by the processor, enables the electronic device to change its operation mode and/or change its settings in response to the received identification signal.

According to another preferred embodiment of the present invention, there is provided an electronic device according to the present disclosure that comprises at least a reader adapted to interact with a passive identification means of the bracket (not shown in the drawings), a processor, and a memory that stores at least a program code, which, when executed by the processor, enables the reader to interact with the passive identification means to receive an identification signal; wherein the electronic device is designed to be placed on a vertical surface by means of a bracket; wherein in a side of the electronic device that faces the vertical surface there is provided a recess to accommodate a ledge formed by the bracket; wherein the bracket for the electronic device placed on a vertical surface is an element that is fixed to a vertical surface to form a ledge, adapted to place the ledge into a recess provided in a side of the electronic device that faces the vertical surface; wherein the ledge comprises at least one ferromagnetic or magnetic element, and the recess holds a corresponding opposite magnetic or ferromagnetic element, so that said opposite element contacts the corresponding ferromagnetic or magnetic element of the bracket to create a magnetic coupling when the ledge is placed into the recess; wherein the recess is designed, so as to provide a shift of the corresponding opposite ferromagnetic or magnetic element relative to the corresponding magnetic or ferromagnetic element of the bracket.

According to another preferred embodiment of the present invention, there is provided a method for controlling an electronic device placed on a vertical surface, the method comprising placing the electronic device on a bracket for an electronic device placed on a vertical surface, so that the device interacts with a passive identification means of the bracket to receive an identification signal, and changing the operation mode of the electronic device and/or change the settings of the electronic device in response to the received identification signal; wherein the bracket for the electronic device placed on a vertical surface is an element that is fixed to a vertical surface to form a ledge, adapted to place the ledge into a recess provided in a side of the electronic device that faces the vertical surface; wherein the ledge comprises at least one ferromagnetic or magnetic element, and the recess holds a corresponding opposite magnetic or ferromagnetic element, so that said opposite element contacts the corresponding ferromagnetic or magnetic element of the bracket to create a magnetic coupling when the ledge is placed into the recess; wherein the recess is designed, so as to provide a shift of the corresponding opposite ferromagnetic or magnetic element relative to the corresponding magnetic or ferromagnetic element of the bracket; wherein the bracket is equipped with a passive identification means, and the electronic device is equipped with at least a reader adapted to interact with said identification means; and wherein the electronic device further comprises at least a processor; and a memory that stores at least a program code, which, when executed by the processor, enables the reader to interact with the passive identification means to receive an identification signal.

Additional alternative embodiments of the present invention are provided below. This disclosure is in no way limiting to the scope of protection granted by the present patent. Rather, it should be noted that the claimed invention can be implemented in different ways, so as to include different components and conditions, or combinations thereof, which are similar to the components and conditions disclosed herein, in combination with other existing and future technologies.

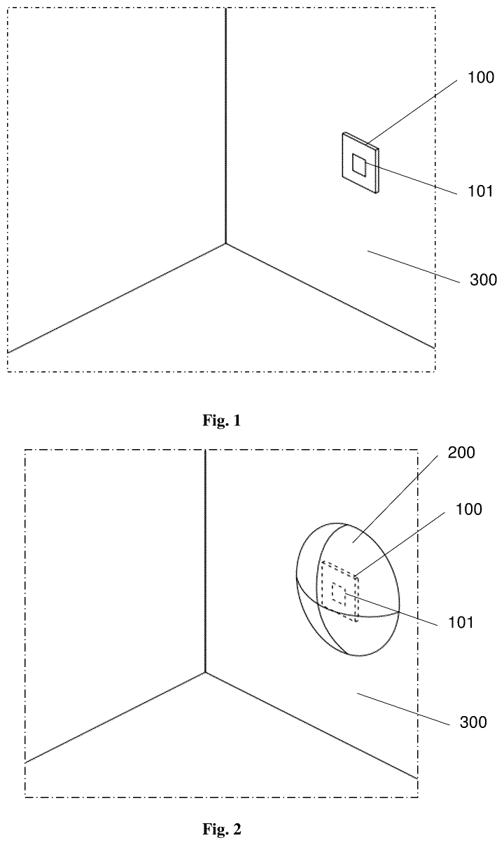

FIG. 1 illustrates an exemplary, non-limiting, embodiment of the proposed bracket 100. Preferably, but not limited to, according to one embodiment, the proposed bracket 100 is a parallelepiped, one side of which faces a vertical surface 300, such as, for example, but not limited to, a building wall or a room wall, a post, etc., wherein surface 300 has enough space for secure placement of bracket 100 on surface 300. Furthermore, for example, but not limited to, bracket 100 can be fixed to surface 300 using any suitable method that is known now or will be known in the future, which provides a sufficiently secure connection between bracket 100 and surface 300, such as, for example, but not limited to, threaded connection, such as, for example, but not limited to, anchor, and/or threaded, and/or screw connection, as well as, but not limited to, glued connection, welded connection, etc. In addition, for example, but not limited to, in case surface 300 is made of a ferromagnetic material or has a ferromagnetic area, the back side of bracket 100 can be equipped with an additional magnetic element (not shown in the drawing) for secure connection with a ferromagnetic surface 300 or a ferromagnetic area thereof. For example, but not limited to, a ferromagnetic area on surface 300 can be made of a soft iron patch (magnetic wallpaper) or the like. Furthermore, but not limited to, in order to fix bracket 100 to surface 300 by means of anchor or threaded connection, surface 300 can be equipped with corresponding holes through which bracket 100 can be fixed to surface 300 by means of a screw, including a self-tapping screw. In case welded connection is used, bracket 100 is, for example, but not limited to, made of metal or at least contains a metallic base (not shown in the drawing) of sufficient thickness that is suitable for forming a welded joint with a metallic surface 300 or a metallic area on surface 300. In case glued connection is used, bracket 100 has, for example, but not limited to, an adhesive base on its back side (not shown in the drawing), such as, for example, but not limited to, a double-sided adhesive tape, whereas surface 300 is chosen, so that sufficient adhesion of the adhesive surface of the tape to surface 300 is provided. Furthermore, but not limited to, bracket 100 can be made of a material or has a base made of a material (not shown in the drawing), which has similar adhesive properties to the glue that is used to glue bracket 100 to surface 300. Therefore, but not limited to, bracket 100 can be fixed 300 using any suitable method that is known now or will be known in the future and therefore will not be described in detail below. Furthermore, it should be generally noted that, when fixed to surface 300, bracket 100 always forms a ledge. Furthermore, but not limited to, the ledge can be formed either directly by the body of bracket 100 or by any protruding part of said body (not shown in the figure). Furthermore, preferably, but not limited to, bracket 100 comprises, and therefore the formed ledge comprises too, at least one magnetic element 101, which is the main magnetic element of bracket 100. Preferably, but not limited to, magnetic element 101 does not occupy the entire surface of the ledge, but is placed in such a way, so as to provide secure magnetic coupling with the opposite ferromagnetic element 201 in recess 202 of device 200, which will be described in more detail below, while maintaining a possibility of shifting ferromagnetic element 201 against magnetic element 101 in order to quickly and conveniently decouple them from each other. Furthermore, but not limited to, it is mainly determined by the fact that tensile strength of a magnetic coupling is much higher than its shear strength, which is especially relevant in case magnetic element 101 is a powerful magnet, such as, for example, but not limited to, a neodymium magnet, which will inevitably require shifting for decoupling.

FIG. 2 illustrates an exemplary, non-limiting, embodiment of device 200 that is connected to bracket 100. Preferably, but not limited to, such device 200 can be predominantly of any suitable shape or size, which are mainly determined by the strength and reliability of the magnetic coupling provided, as well as by the strength and reliability of connection between bracket 100 and surface 300. Furthermore, but not limited to, in this embodiment, device 200 is not predominantly flat, i.e., at least the thickness of its part that protrudes over the ledge formed by bracket 100 is at least twice the distance of the ledge from surface 300. Furthermore, but not limited to, the shape of device 200 is mainly determined by its purpose.

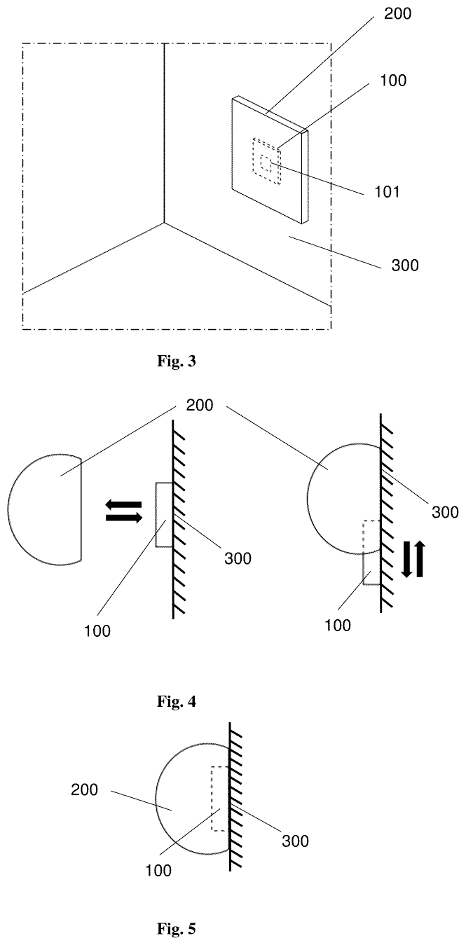

FIG. 3 illustrates a different exemplary, non-limiting, embodiment of device 200 that is connected to bracket 100. Preferably, but not limited to, in this different embodiment, device 200 is predominantly flat, i.e., at least the thickness of its part that protrudes over the ledge formed by bracket 100 is at less than twice the distance of the ledge from surface 300. Furthermore, but not limited to, the shape of device 200 is also mainly determined by its purpose.

FIG. 4 illustrates exemplary, non-limiting, options of connecting bracket 100 and device 200. As will be shown below, device 200 may comprise recess 202, which can accommodate the ledge formed by bracket 100. Furthermore, but not limited to, it is generally possible to provide two connection options. According to the first option, but not limited to, as shown in the left part of FIG. 4, recess 202 of device 200 is slid onto the ledge formed by bracket 100 in horizontal direction toward surface 300; wherein, therefore, recess 202 in device 200 is designed, so that it has walls on all sides, thus not allowing device 200 to shift against bracket 100 in any direction. Therefore, but not limited to, in order to disconnect device 200 from bracket 100, one needs at least to turn device 200 along an axis perpendicular to surface 300, as will be shown below, thereby performing said shift. According to the second option, but not limited to, as shown in the right part of FIG. 4, recess 202 of device 200 is slid onto the ledge formed by bracket 100 in horizontal or vertical direction parallel to surface 300; wherein, therefore, recess 202 in device 200 is designed, so that it has walls on all sides but one, thus allowing device 200 to shift against bracket 100 in the direction of the missing wall. Therefore, but not limited to, in order to disconnect device 200 from bracket 100, one needs at least to slide device 200 in the direction opposite to the missing wall, i.e., if recess 202 does not have a bottom wall, then device 200 should slide upwards, etc., thereby performing said shift. FIG. 5 illustrates an exemplary, non-limiting, way of placing bracket 100 in recess 202 of device 200. At the same time, but not limited to, although it is not shown in the drawing, it should be obvious to a person having ordinary skill in the art that the back wall of device 200 itself does not necessarily have to contain recess 202, since there may be provided a base in device 200 that will contain a suitable recess 202.

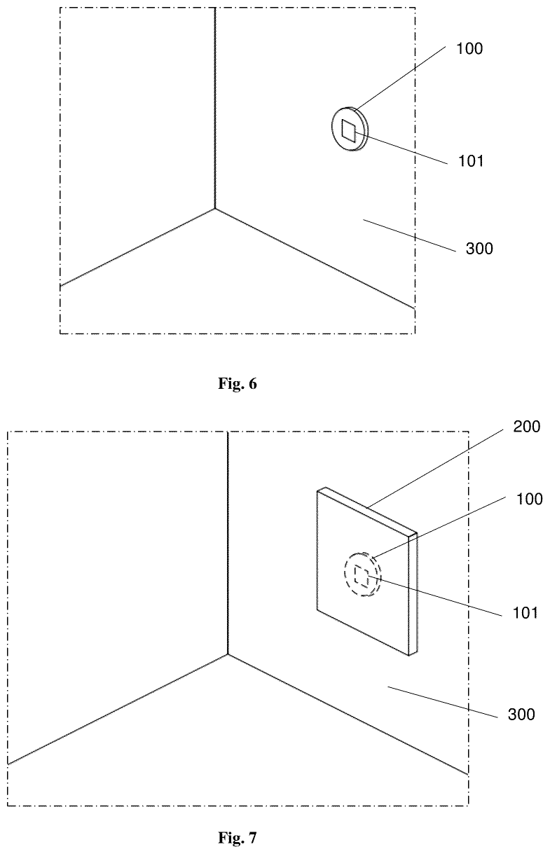

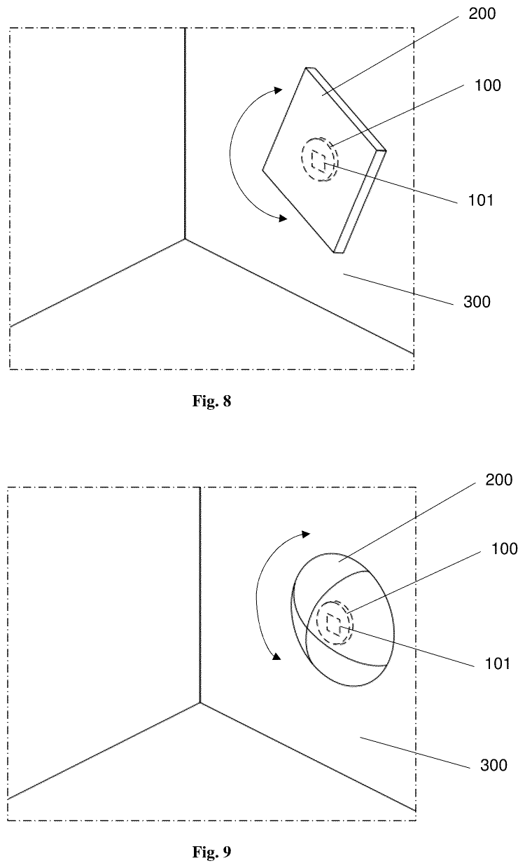

At the same time, it should be obvious to a person having ordinary skill in the art that, when recess 202 has the same shape and size as bracket 100, and bracket 100 has corners, then it will be difficult or even impossible to shift device 200 by turning it. FIG. 6 illustrates a different exemplary, non-limiting, embodiment of the proposed bracket 100. In contrast to the ones disclosed above with reference to FIG. 1, the embodiment of bracket 100 with reference to FIG. 6 is at least not made in the form of a rectangle, as was shown with reference to FIG. 1. Such bracket 100 according to FIG. 6 is connected with device 200 in the same way as was shown with reference to FIG. 5 (left side) and has almost the same functionality except the fact that its shape and size are chosen, so that recess 202 can be rotated around the ledge formed by bracket 100. Furthermore, but not limited to, such bracket 100 can be additionally equipped with a positioning means, for example, a small-sized recess in the surface of bracket 100, into which an opposite small-sized ledge can fit, which is provided on the surface of recess 202 that touches the surface of bracket 100 (not shown in the drawing). This positioning means can be used for exact placement of device 200 relative to surface 300. FIG. 7 illustrates an exemplary, non-limiting, embodiment of a predominantly flat device 200 that is connected to bracket 100 according to FIG. 6. FIG. 8 illustrates an exemplary, non-limiting, embodiment of shifting metallic element 201 (not shown in this drawing) relative to magnetic element 101 in device 200 with reference to FIG. 7 when using bracket 100 according to FIG. 6. FIG. 9 illustrates an exemplary, non-limiting, embodiment of shifting ferromagnetic element 201 (not shown in this drawing) relative to magnetic element 101 in another embodiment of device 200 when using bracket 100 according to FIG. 6.

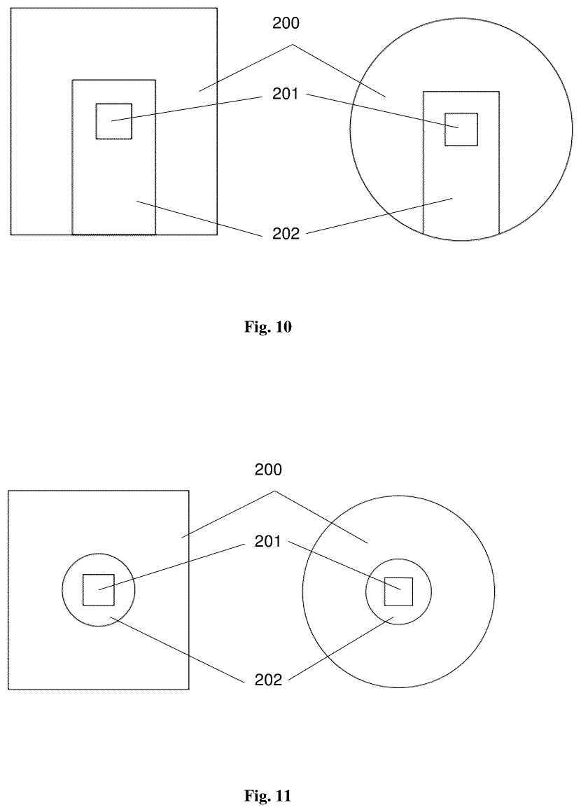

FIG. 10 illustrates an exemplary, non-limiting, rear view of two exemplary embodiments of device 200 designed for use with bracket 100 according to FIG. 1. Furthermore, but not limited to, as was mentioned above, the shape of device 200 is not essential, since it can be determined by the device's purpose, but at the same time, the back side of device 200 or the back side of the base of device 200 contains recess 202, which houses ferromagnetic element 201, which is the opposite element for magnetic element 101. Such recess 202, although the cut is not shown in the drawing, obviously, does not have one of the walls, thus enabling ferromagnetic element 201 at least shift in relation to magnetic element 101 in a horizontal or vertical direction parallel to surface 300. At the same time, it should be obvious to a person having ordinary skill in the art that in case the size of bracket 100 allows it, the elements can shift against each other by turning recess 202 around the ledge formed by bracket 100 as well. At the same time, it should be obvious to a person having ordinary skill in the art that device 200 can be placed onto two or more brackets 100, depending on the size of device 200, and it should be noted that such brackets 100 have to be positioned coaxially on surface 300, so that all ferromagnetic elements 201 shift simultaneously relative to all corresponding magnetic elements 101. FIG. 11 illustrates an exemplary, non-limiting, rear view of two exemplary embodiments of device 200 designed for use with bracket 100 according to the embodiment with reference to FIG. 6. In contrast to disclosed above with reference to FIG. 10, recesses 202, in this case, have walls on all sides and are essentially made in a round shape or another shape, so that ferromagnetic element 201 can shift relative to magnetic element 101 solely by rotating recess 202 around the ledge formed by bracket 100.

At the same time, it should be obvious to a person having ordinary skill in the art that magnetic element 101 and ferromagnetic element 201 can be switched, i.e., so that device 200 comprises magnetic element 101 and bracket 100 comprises ferromagnetic element 201, respectively. Moreover, but not limited to, device 200 can be provided with its own magnetic element, wherein bracket 100 still has magnetic element 101, and wherein said magnetic elements are unlike, thus attracting to each other, which can provide a more secure coupling than a magneto-ferromagnetic coupling.

In addition, but not limited to, there may be provided bracket 100 for electronic device 200 placed on a vertical surface, the bracket being an element that is fixed to a vertical surface to form a ledge, adapted to place the ledge into recess 202 provided in a side of electronic device 200 that faces the vertical surface; wherein the ledge comprises at least one ferromagnetic or magnetic element 101, and recess 202 holds a corresponding opposite magnetic or ferromagnetic element 201, so that said opposite element contacts the corresponding ferromagnetic or magnetic element 101 of the bracket to create a magnetic coupling when the ledge is placed into recess 202; wherein recess 202 is designed, so as to provide a shift of the corresponding opposite ferromagnetic or magnetic element 201 relative to the corresponding magnetic or ferromagnetic element 101 of bracket 100; wherein bracket 100 is equipped with a passive identification means (not shown in the drawings), and electronic device 200 is equipped with reader 203 adapted to interact with said identification means; and wherein electronic device 200 comprises at least processor 204, and memory 205 that stores at least a program code, which, when executed by processor 204, enables reader 203 to interact with the passive identification means to receive an identification signal.

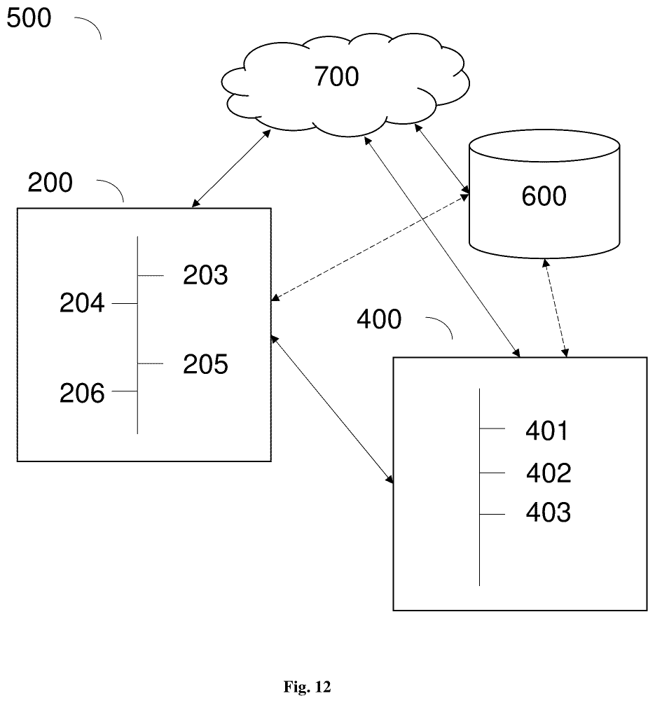

Therefore, generally, but not limited to, there may be provided an electronic device 200 according to the present disclosure, the overall scheme of which is shown in FIG. 12, the device comprising at least reader 203 adapted to interact with a passive identification means of the bracket (not shown in the drawings), processor 204, and memory 205 that stores at least a program code, which, when executed by processor 204, enables reader 203 to interact with the passive identification means to receive an identification signal; wherein electronic device 200 is designed to be placed on a vertical surface by means of bracket 100; wherein in a side of electronic device 200 that faces the vertical surface there is provided recess 202 to accommodate a ledge formed by bracket 100; wherein bracket 100 for electronic device 200 placed on a vertical surface is an element that is fixed to a vertical surface to form a ledge, adapted to place the ledge into recess 202 provided in a side of electronic device 200 that faces the vertical surface; wherein the ledge comprises at least one ferromagnetic or magnetic element 101, and recess 202 holds a corresponding opposite magnetic or ferromagnetic element 201, so that said opposite element contacts the corresponding ferromagnetic or magnetic element 101 of the bracket to create a magnetic coupling when the ledge is placed into recess 202; wherein recess 202 is designed, so as to provide a shift of the corresponding opposite ferromagnetic or magnetic element 201 relative to the corresponding magnetic or ferromagnetic element 101 of bracket 100.

Furthermore, but not limited to, electronic device 200 can be chosen from any of the acoustic device 200, lighting device 200, IoT device 200, image display device 200, or be made of a combination thereof. Furthermore, but not limited to, acoustic device 200, accordingly, additionally comprises at least a sound output device, such as, for example, but not limited to, a speaker, which is widely used in the art for sound output and is therefore not described in any further detail. Furthermore, but not limited to, lighting device 200, accordingly, additionally comprises at least a light source, such as, for example, but not limited to, an LED light source or the like, which is widely used in the art for lighting and is therefore not described in any further detail. Furthermore, but not limited to, IoT device 200, accordingly, additionally comprises at least a receiver and a transmitter adapted to transmit a control signal, wherein it should be generally noted that IoT device 200 for bracket 100 can be both a repeater and a hub, or it can be equipped with hub functions, i.e., for example, but not limited to, its memory may store a program code for generating a control signal for other devices within the IoT system in response to the received identification signal; otherwise, the organizing principles of IoT systems are widely known in the art and are therefore not described in any further detail. Furthermore, but not limited to, image display device 200, accordingly, additionally comprises at least a display, which is widely used in the art for image output and is therefore not described in any further detail.

Furthermore, but not limited to, the passive identification means of the bracket can be, for example, but not limited to, one of the 2D graphic code, such as, for example, a quick response code (QR code), or a bar code, or an RFID tag, or a combination thereof. Furthermore, depending on the passive identification means used in bracket 100, electronic device 200 includes a corresponding suitable reader 203. For example, but not limited to, if a 2D graphic code was selected as the passive identification means of bracket 100, then reader 203 may be a laser scanner, or a video scanner, which are widely used in the art and are therefore not described in any further detail. For example, but not limited to, if an RFID tag was selected as the passive identification means of bracket 100, then reader 203 may be, for example, an NFC module, which is widely used in the art and is therefore not described in any further detail. Preferably, but not limited to, reader 203 interacts with the corresponding passive identification means at the moment when the magnetic coupling is formed. In addition, for example, but not limited to, an electrical key may be provided, which activates at the moment when the magnetic coupling is formed, thereby enabling reader 203 to activate; or, for example, a spatial positioning means for electronic device 200 can be provided, such as, for example, but not limited to, a gyroscope, which, when placed in a specific position, indicates that reader 203 needs to activate, the position corresponding to the position of electronic device 200, in which the magnetic coupling is formed; or bracket 100 may additionally comprise, for example, but not limited to, a grid-connectable power source for the power source of electronic device 200, for which purpose the surface of bracket 100 may be provided with electrical contacts for forming the electrical coupling when the magnetic coupling is formed, for which purpose, for example, but not limited to, recess 202 may also be provided with counter electrical contacts connected to a power controller; wherein, when the electrical coupling is formed, not only the power source of electronic device 200 can be recharged from the grid, but also an activation signal for reader 203 can be generated. At the same time, it should be obvious to a person having ordinary skill in the art that the electronic device is necessarily equipped with one or several power sources, such as electric batteries, including disposable and/or rechargeable batteries and/or storage batteries, i.e., a power source in electronic device 200 is considered inherent. In addition, it should also be obvious to a person skilled in the art that the electronic device has a suitable housing that protects its components from external impacts and/or unauthorized access, i.e., the housing of the electronic device is considered inherent.

In addition, but not limited to, electronic device 200 can be quipped with a wireless communication means or another interface for user device 400 to connect to it for initial configuration. In this case, user device 400 may be, but is not limited to, a smartphone, a tablet, a laptop, a PC, etc. Most typically, such user device 400 comprises at least input/output devices 401, such as, for example, a keyboard, manipulators, displays, including touchscreens, processor 402, and memory 403 that stores a program code that allows at least to send a packet of settings to electronic device 200. In addition, preferably, but not limited to, the packet of settings includes at least the unique identifier of bracket 100, as well as scripts and/or settings that are associated with this unique identifier, to be implemented and/or used by electronic device 200; wherein, but not limited to, electronic device 200 can therefore have the corresponding initial settings stored in memory 205 as, for example, but not limited to, a plurality of unique identifiers of brackets 100, each of them associated with a corresponding script and/or corresponding settings to be implemented and/or used by electronic device 200. In addition, said initial settings can be modified by a corresponding packet of settings that is generated and sent to electronic device 200 by means of user device 400. However, but not limited to, the use of user device 400 is optional, and electronic device 200 can be itself equipped with input/output devices 206, such as, for example, but not limited to, keys, buttons, a keyboard, a manipulator, a display, including a touchscreen, a voice interface, etc. In this case, scripts and settings can be provided for each bracket 100 without using user device 400 directly, by the user interacting with electronic device 200.

Therefore, preferably, but not limited to, as is shown in FIG. 12, there may be provided system 500 for controlling electronic device 200, which may additionally include a server, which, for example, but not limited to, is based on user device 400 or is a standalone device 400. At the same time, preferably, but not limited to, processor 204, 402 is both the chip itself and the rest of the processor and/or microprocessor components, such as, for example, but not limited to, microcontrollers, drivers, cash memory and other electronic devices. It should be generally noted that the processor allows to implement the program code that enables electronic device 200 to perform any working script and/or implement any settings. In addition, for example, but not limited to, memory 205, 403 (computer-readable medium 205, 403) may comprise a non-volatile memory (NVRAM); a random-access memory (RAM); a read-only memory (ROM); an electrically erasable programmable read-only memory (EEPROM); a flash drive or other memory technologies; a CD-ROM, a digital versatile disk (DVD) or other optical/holographic media; magnetic tapes, magnetic film, a hard disk drive or any other magnetic drive; and any other medium capable of storing and encoding the necessary information. In addition, but not limited to, memory 205, 403 comprises a computer-readable medium based on the computer memory, either volatile or non-volatile, or a combination thereof. In addition, but not limited to, exemplary hardware devices include solid-state drives, hard disk drives, optical disk drives, etc. For instance, but not limited to, computer-readable medium 205, 403 (memory 205, 403) is not a temporary memory (i.e., a permanent, non-transitive memory), and therefore it does not contain a temporary (transitive) signal. In addition, but not limited to, memory 205, 403 may store an exemplary environment, in which a packet of settings can be generated in order to be transferred to electronic device 200, by means of computer instructions or codes, including those stored in memory 403 of server 400. In addition, but not limited to, system 500 may further comprise a database 600. Database 600 may be, but not limited to, a hierarchical database, a network database, a relational database, an object database, an object-oriented database, an object-relational database, a spatial database, a combination of two or more said databases, etc. Furthermore, but not limited to, database 600 at least stores unique identifiers for brackets 100 and initial settings associated with them, including modified initial settings, i.e. current settings for corresponding electronic devices 200, as well as it may store data for analysis, pre-written scripts and other information in memory 205, 403 or in a suitable memory of a different computer device that is connected with electronic device 200 and/or server 400, which may be, but not limited to, a memory that is identical to any of the memories 205, 403 as was disclosed above, and which can be accessed through means of server 400 and network 700. In addition, but not limited to, there is provided a server 400, which, in addition to the functions mentioned above, stores and facilitates the execution of computer-readable commands and codes disclosed herein, which, accordingly, won't be described again. In addition, but not limited to, server 400, in addition to the functions mentioned above, is capable of controlling the data exchange within system 500. In addition, but not limited to, data exchange within system 500 is performed with the help of one or more data exchange networks 700. In addition, but not limited to, data exchange networks 700 may include, but not limited to, one or more local area networks (LAN) and/or wide area networks (WAN), or may be represented by the Internet or Intranet, or a virtual private network (VPN), or a combination thereof, etc. In addition, but not limited to, server 400 is further capable of providing a virtual computer environment for the components of the system to interact with each other. In addition, but not limited to, network 700 enables interaction between electronic device 200, user device 400 and/or server 400 and, optionally, database 600. In addition, but not limited to, database 600 may be located in the memory 205, 403. In addition, most typically, but not limited to, components of electronic device 200 and components of user device 400 or server 400 are interconnected, including via any kind of data bus.

Preferably, but not limited to, the proposed system operates as follows. Several brackets 100 with passive identification means are placed on a vertical surface 300 in one or more rooms or outdoors. First, working scripts and/or settings are provided for corresponding electronic devices 200 by means of user device 400 and/or system 500; wherein scripts and/or settings are provided in relation to corresponding brackets 100; and wherein, but not limited to, the initial settings can be either received from database 600 or initially stored in memory 205 of electronic device 200, for example, in case electronic device 200 is part of a set that includes several brackets 100. By placing brackets 100, it is possible to accurately determine the environment in which electronic device 200 will be located, which allows to provide it with the most suitable for the user operation mode and/or settings. Furthermore, but not limited to, the operation mode may also include a specific working script, i.e., a one-time or recurring sequence of procedures and/or operations to be performed by electronic device 200. Accordingly, but not limited to, when electronic device 200 is placed on bracket 100, preferably, at the moment the magnetic coupling is formed, reader 203 is activated, which interacts with the passive identification means of bracket 100 in order to receive the identification signal, in response to which the operation mode and/or the settings of electronic device 200 are changed. When electronic device 200 is disconnected from bracket 100, it can, for example, but not limited to, continue to operate in the mode and with the settings that correspond to the bracket 100, from which device 200 was disconnected last, or its operation mode and/or settings can be changed as soon as it is disconnected, i.e. the magnetic coupling is terminated. After that, device 200 can be placed on another bracket 100 that has a unique identifier associated with a different operation mode and settings. In this way, operation modes of the same electronic device can easily be changed depending on user preferences and/or environment in which device 200 is used. Taking for example, but not limited to, acoustic device 200, one bracket 100 could initiate the acoustic device's media player subroutine to play one musical content sequence at one sound level, but when device 200 is connected to another bracket 100, it would play a different musical content sequence at a different sound level. That is, first, device 200 can be placed on bracket 100, for example, in a gym, to play loud music for training sessions, and then device 200 can be placed on bracket 100 in a living room to play soft and calm music. In a similar way, corresponding scripts and settings can be also provided for lighting device 200, IoT device 200, or image display device 200; wherein, for example, but not limited to, if electronic device 200 is an IoT device, then a control signal can be generated or at least sent, which allows other devices in the IoT system to change their operation modes and/or settings, i.e. for IoT device 200, the change of operation mode and/or settings may consist in, for example, but not limited to, sending or generating and sending a control signal for other IoT devices in the IoT system.

Therefore, there may also be provided a set including at least any bracket 100 disclosed above and at least any device 200 disclosed above.

Therefore, there may also be provided a method for controlling an electronic device placed on a vertical surface, the method comprising placing electronic device 200 on bracket 100 for an electronic device placed on a vertical surface, so that the device interacts with a passive identification means of bracket 100 to receive an identification signal, and changing the operation mode of electronic device 200 and/or change the settings of electronic device 200 in response to the received identification signal; wherein bracket 100 for electronic device 200 placed on a vertical surface is an element that is fixed to a vertical surface to form a ledge, adapted to place the ledge into recess 202 provided in a side of electronic device 200 that faces the vertical surface; wherein the ledge comprises at least one ferromagnetic or magnetic element 101, and recess 202 holds a corresponding opposite magnetic or ferromagnetic element 201, so that said opposite element contacts the corresponding ferromagnetic or magnetic element 101 of the bracket to create a magnetic coupling when the ledge is placed into recess 202; wherein recess 202 is designed, so as to provide a shift of the corresponding opposite ferromagnetic or magnetic element 201 relative to the corresponding magnetic or ferromagnetic element 101 of bracket 100; wherein bracket 100 is equipped with a passive identification means, and electronic device 200 is equipped with at least reader 203 adapted to interact with said identification means; and wherein electronic device 200 further comprises at least processor 204, and memory 205 that stores at least a program code, which, when executed by the processor, enables the reader to interact with the passive identification means to receive an identification signal.

The present disclosure of the claimed invention demonstrates only certain exemplary embodiments of the invention, which by no means limit the scope of the claimed invention, meaning that it may be embodied in alternative forms that do not go beyond the scope of the present disclosure and which may be obvious to persons having ordinary skill in the art.

1. A bracket for an electronic device placed on a vertical surface, the bracket being an element that is fixed to a vertical surface to form a ledge, adapted to place the ledge into a recess provided in a side of the electronic device that faces the vertical surface; wherein the ledge comprises at least one ferromagnetic or magnetic element, and the recess holds a corresponding opposite magnetic or ferromagnetic element, so that said opposite element contacts the corresponding ferromagnetic or magnetic element of the bracket to create a magnetic coupling when the ledge is placed into the recess; wherein the recess is designed, so as to provide a shift of the corresponding opposite ferromagnetic or magnetic element relative to the corresponding magnetic or ferromagnetic element of the bracket; wherein the bracket is equipped with a passive identification means, and the electronic device is equipped with a reader adapted to interact with said identification means; and wherein the electronic device comprises at least a processor; and a memory that stores at least a program code, which, when executed by the processor, enables the reader to interact with the passive identification means to receive an identification signal.

2. The bracket of claim 1, characterized in that the electronic device is an acoustic device that additionally comprises at least a sound output means controlled by the processor.

3. The bracket of claim 1, characterized in that the electronic device is a lighting device that additionally comprises at least a light source controlled by the processor.

4. The bracket of claim 1, characterized in that the electronic device is an IoT device that additionally comprises at least a receiver and a transmitter adapted to transmit a control signal, both the receiver and the transmitter being controlled by the processor.

5. The bracket of claim 1, characterized in that the electronic device is an image output device that additionally comprises at least a display controlled by the processor.

6. The bracket of claim 1, characterized in that the memory additionally stores at least a program code, which, when executed by the processor, enables the electronic device to change its operation mode and/or change its settings in response to the received identification signal.

7. The bracket of claim 2, characterized in that the memory additionally stores at least a program code, which, when executed by the processor, enables the electronic device to change its operation mode and/or change its settings in response to the received identification signal.

8. The bracket of claim 3, characterized in that the memory additionally stores at least a program code, which, when executed by the processor, enables the electronic device to change its operation mode and/or change its settings in response to the received identification signal.

9. The bracket of claim 4, characterized in that the memory additionally stores at least a program code, which, when executed by the processor, enables the electronic device to change its operation mode and/or change its settings in response to the received identification signal.

10. The bracket of claim 5, characterized in that the memory additionally stores at least a program code, which, when executed by the processor, enables the electronic device to change its operation mode and/or change its settings in response to the received identification signal.
